(19) United States
(12) Patent Application Publication
(10) Pub. No.: US 2026/0206235 A1
(43) Pub. Date: Jul. 16, 2026

(54) DUAL-OXIDE ACCESS TRANSISTORS FOR A RESISTIVE RANDOM-ACCESS MEMORY DEVICE

(71) Applicant: GlobalFoundries U.S. Inc., Malta, NY (US)

(72) Inventors: Venkatesh Periyapatna Gopinath, Fremont, CA (US); Hong Sik Yoon, Dresden (DE); Violetta Sessi, Dresden (DE); Venkata Sudheer Nune, Dresden (DE); Sandeep Puri, Ballston Lake, NY (US)

(21) Appl. No.: 19/023,795

(22) Filed: Jan. 16, 2025

(51) Int. Cl. H10B 63/00

(52) U.S. Cl. CPC H10B 63/30

(57) ABSTRACT

Structures including an access transistor and a resistive memory element, and methods of forming such structures. The structure comprises an access transistor including a semiconductor layer, a first source/drain region, a second source/drain region, a gate dielectric layer on the semiconductor layer, and a gate electrode overlapped with the gate dielectric layer. The gate dielectric layer has a first portion with a first thickness adjacent to the first source/drain region and a second portion with a second thickness adjacent to the second source/drain region, and the first thickness is greater than the second thickness. The structure further comprises a resistive memory element that is coupled to the first source/drain region of the access transistor.

### BACKGROUND

This disclosure relates to integrated circuits and semiconductor device fabrication and, more specifically, to structures including an access transistor and a resistive memory element, and methods of forming such structures.

A resistive random-access memory device represents one category of embedded non-volatile memory technology. A bitcell of a resistive random-access memory device typically includes a resistive memory element and an access transistor that controls operations used to write, erase, and read the resistive memory element. Because resistive memory elements are non-volatile, bits of data are retained as stored content by the resistive memory elements when the resistive random-access memory device is unpowered. The non-volatility of a resistive random-access memory device contrasts with volatile memory technologies, such as a static random-access memory device in which the stored content is eventually lost when unpowered and a dynamic random-access memory device in which the stored content is lost unless periodically refreshed.

Improved structures including an access transistor and a resistive memory element, and methods of forming such structures, are needed.

### SUMMARY

In an embodiment, a structure comprises an access transistor including a semiconductor layer, a first source/drain region, a second source/drain region, a gate dielectric layer on the semiconductor layer, and a gate electrode overlapped with the gate dielectric layer. The gate dielectric layer has a first portion with a first thickness adjacent to the first source/drain region and a second portion with a second thickness adjacent to the second source/drain region, and the first thickness is greater than the second thickness. The structure further comprises a resistive memory element that is coupled to the first source/drain region of the access transistor.

In an embodiment, a method comprises forming an access transistor including a first source/drain region, a second source/drain region, a gate dielectric layer on a semiconductor layer, and a gate electrode overlapped with the gate dielectric layer. The gate dielectric layer has a first portion with a first thickness adjacent to the first source/drain region and a second portion with a second thickness adjacent to the second source/drain region, and the first thickness is greater than the second thickness. The method further comprises forming a resistive memory element that is coupled to the first source/drain region of the access transistor.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals are used to indicate like features in the various views.

FIG. 1 is a cross-sectional view of a structure at an initial fabrication stage of a processing method in accordance with an embodiment of the invention.

FIG. 2 is a cross-sectional view of the structure at a fabrication stage subsequent to FIG. 1.

FIG. 3 is a cross-sectional view of the structure at a fabrication stage subsequent to FIG. 2.

FIG. 4 is a cross-sectional view of the structure at a fabrication stage subsequent to FIG. 3.

FIG. 5 is a cross-sectional view of the structure at a fabrication stage subsequent to FIG. 4.

FIG. 6 is a cross-sectional view of the structure at a fabrication stage subsequent to FIG. 5.

### DETAILED DESCRIPTION

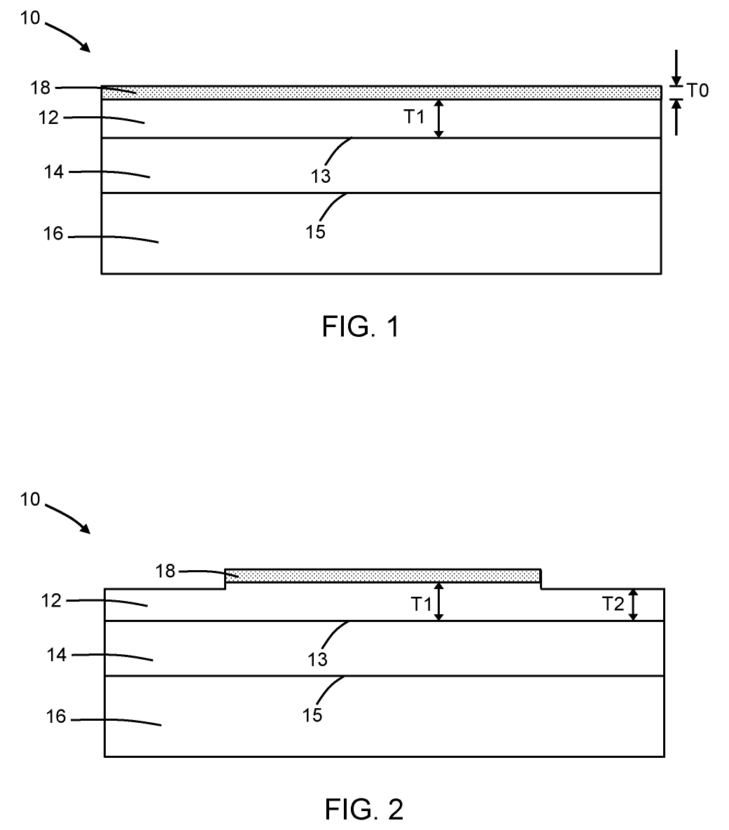

With reference to FIG. 1 and in accordance with embodiments of the invention, a structure 10 includes a semiconductor layer 12, a dielectric layer 14, and a semiconductor substrate 16. In an embodiment, the semiconductor layer 12 may be comprised of a semiconductor material, such as single-crystal silicon. In an embodiment, the dielectric layer 14 may be comprised of a dielectric material, such as silicon dioxide, and the semiconductor substrate 16 may be comprised of a semiconductor material, such as single-crystal silicon. The dielectric layer 14 may have an interface 13 representing a boundary with the semiconductor layer 12 and an interface 15 representing a boundary with the semiconductor substrate 16. In an embodiment, the dielectric layer 14 may be a buried oxide layer of a silicon-on-insulator substrate, and the dielectric layer 14 may fully separate the semiconductor layer 12 from the semiconductor substrate 16.

The semiconductor layer 12 may have a thickness T1 relative to the interface 13 with the dielectric layer 14. In an embodiment, the thickness T1 of the semiconductor layer 12 may be suitable for fabricating fully-depleted silicon-on-insulator device structures. In an embodiment, the thickness T1 may range from about 4 nanometers to about 20 nanometers.

A dielectric layer 18 may be formed on, and over, the semiconductor layer 12. In an embodiment, the dielectric layer 18 may fully overlie the semiconductor layer 12. The dielectric layer 18 may have a thickness T0 relative to a top surface of the semiconductor layer 12. In an embodiment, the dielectric layer 18 may be comprised of a dielectric material that is an electrical insulator. In an embodiment, the dielectric layer 18 may be comprised of silicon dioxide that is formed by either a deposition process or an oxidation process.

With reference to FIG. 2 in which like reference numerals refer to like features in FIG. 1 and at a subsequent fabrication stage, the dielectric layer 18 may be patterned by lithography and etching processes. In an embodiment, an etch mask may be formed by a lithography process over a section of the dielectric layer 18, and unmasked sections of the dielectric layer 18 may be etched and removed by an etching process. The etch mask may be comprised of an organic photoresist applied by a spin coating process, pre-baked, exposed to light projected through a photomask, baked after exposure, and developed with a chemical developer to define a shape at an intended location on the dielectric layer 18. The etching process may be a reactive ion etching process, and the etch mask may be stripped following the conclusion of the etching process.

Partially-etched sections of the semiconductor layer 12, which are arranged adjacent to the patterned section of the dielectric layer 18, may be recessed and thinned by the etching process after the unmasked sections of the dielectric layer 18 are etched and removed. As a result, the partially-etched sections of the semiconductor layer 12 may have a thickness T2 relative to the interface 13, whereas the unetched section of the semiconductor layer 12 underlying the patterned dielectric layer 18 may have the thickness T1 that is greater than the thickness T2. In an embodiment, the thickness T2 may range from about 4 nanometers to about 20 nanometers.

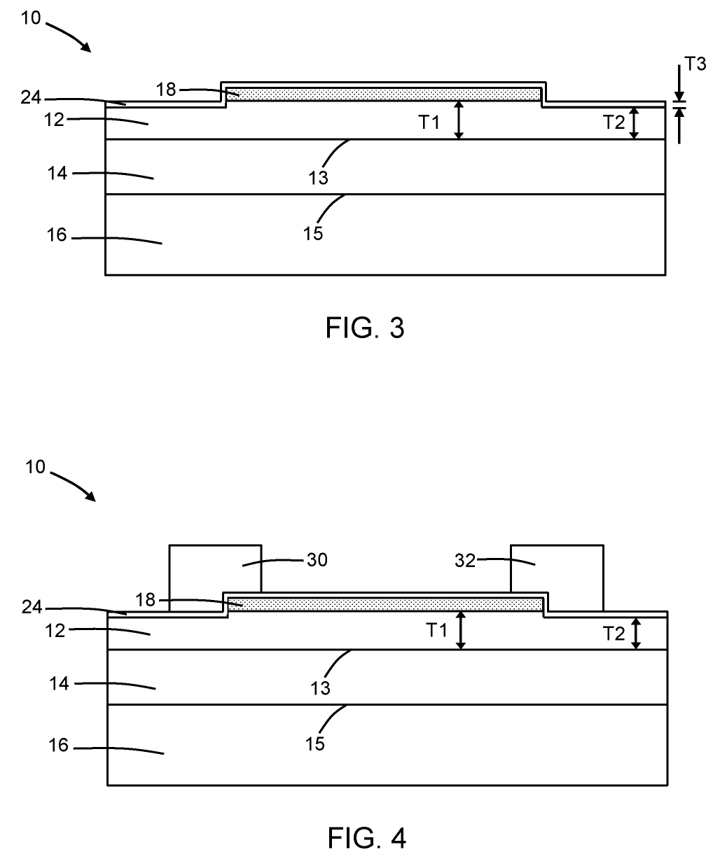

With reference to FIG. 3 in which like reference numerals refer to like features in FIG. 2 and at a subsequent fabrication stage, a dielectric layer 24 may be formed on, and over, the patterned dielectric layer 18 and the partially-etched sections of the semiconductor layer 12 adjacent to the patterned dielectric layer 18. In an embodiment, the dielectric layer 24 may conformally coat the patterned dielectric layer 18 and the partially-portions of the semiconductor layer 12. The dielectric layer 24 may have a thickness T3 relative to a top surface of the semiconductor layer 12 and a top surface of the patterned dielectric layer 18. In an embodiment, the dielectric layer 24 may be comprised of a dielectric material that is an electrical insulator. In an embodiment, the dielectric layer 18 and the dielectric layer 24 may comprise the same dielectric material. In an embodiment, the dielectric layer 24 may be comprised of silicon dioxide formed by, for example, a deposition process.

With reference to FIG. 4 in which like reference numerals refer to like features in FIG. 3 and at a subsequent fabrication stage, a gate electrode 30 and a gate electrode 32 may be formed with a laterally-spaced arrangement on the dielectric layer 24. The gate electrode 30 overlaps with an edge of the dielectric layer 18, and the gate electrode 32 overlaps with an opposite edge of the dielectric layer 18. The gate electrodes 30, 32 may be comprised of a conductor, such as doped polysilicon. The gate electrodes 30, 32 may be formed by depositing a layer of the conductor and patterning the layer with lithography and etching processes.

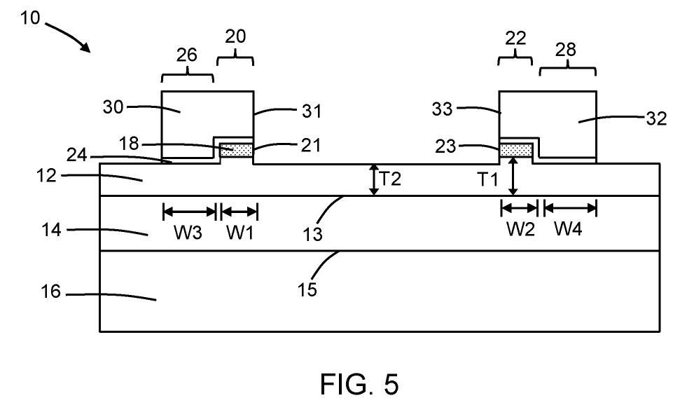

With reference to FIG. 5 in which like reference numerals refer to like features in FIG. 4 and at a subsequent fabrication stage, the dielectric layer 18 and dielectric layer 24 may be patterned by an etching process to form a section 20 of the dielectric layer 18, a section 22 of the dielectric layer 18, a section 26 of the dielectric layer 24, and a section 28 of the dielectric layer 24. The gate electrodes 30, 32 may provide self-alignment of the patterning during the etching process. In an embodiment, the etching process may be a reactive ion etching process. The section of the semiconductor layer 12 between the section 20 of the dielectric layer 18 and the section 22 of the dielectric layer 18 may be partially etched and thinned by the etching process to have the thickness T2 relative to the interface 13.

The section 20 of the dielectric layer 18 may have a side edge 21 that is aligned with a sidewall 31 of the gate electrode 30. The section 22 of the dielectric layer 18 may have a side edge 23 that faces toward the side edge 21 and that is aligned with a sidewall 33 of the gate electrode 32. The section 20 of the dielectric layer 18 may have a width W1 relative to the side edge 21, and the section 22 of the dielectric layer 18 may have a width W2 relative to the side edge 23. The section 26 of the dielectric layer 24 may have a width W3, and the section 28 of the dielectric layer 24 may have a width W4. In an embodiment, the width W3 may be greater than the width W1, and the width W4 may be greater than the width W2.

The gate electrode 30 may include a portion that overlaps with the section 20 of the dielectric layer 18 and an adjacent portion that overlaps with the section 26 of the dielectric layer 24. The dielectric layer 24 includes another section that is arranged between the section 20 of the dielectric layer 18 and the overlapping portion of the gate electrode 30, and that has a width approximately equal to the width W1 of the section 20. The section 26 of the patterned dielectric layer 24, the section 20 of the patterned dielectric layer 18, and the section of the patterned dielectric layer 24 overlapped with the section 20 represent a multiple-thickness gate dielectric layer. The multiple-thickness gate dielectric layer beneath the gate electrode 30 has a thin portion that includes the section 26 of the dielectric layer 24 and that has the thickness T3 of the dielectric layer 24. The multiple-thickness gate dielectric layer beneath the gate electrode 30 has a thick portion that includes the section 20 of the dielectric layer 18 and the overlapping section of the dielectric layer 24 and that has a thickness given by the sum of the thickness T3 and the thickness T0, which is greater than the thickness T3 of the thin portion of the multiple-thickness gate dielectric layer. The thin and thick portions of the multiple-thickness gate dielectric layer transition at a step in the dielectric layer 24 resulting from the section 20 of the dielectric layer 18.

The gate electrode 32 may include a portion that overlaps with the section 22 of the dielectric layer 18 and an adjacent portion that overlaps with the section 28 of the dielectric layer 24. The dielectric layer 24 includes another section that is arranged between the section 22 of the dielectric layer 18 and the overlapping portion of the gate electrode 32, and that has a width approximately equal to the width W2 of the section 22. The section 28 of the patterned dielectric layer 24, the section 22 of the patterned dielectric layer 18, and the section of the patterned dielectric layer 24 overlapped with the section 22 represent a multiple-thickness gate dielectric layer. The multiple-thickness gate dielectric layer beneath the gate electrode 32 has a thin portion that includes the section 28 of the dielectric layer 24 and that has the thickness T3 of the dielectric layer 24. The multiple-thickness gate dielectric layer beneath the gate electrode 32 has a thick portion that includes the section 22 of the dielectric layer 18 and the overlapping section of the dielectric layer 24 and that has a thickness given by the sum of the thickness T3 and the thickness T0, which is greater than the thickness T3 of the thin portion of the multiple-thickness gate dielectric layer. The thin and thick portions of the multiple-thickness gate dielectric layer transition at a step in the dielectric layer 24 resulting from the section 22 of the dielectric layer 18.

The sections of the semiconductor layer 12 adjoining, and beneath, the overlying sections 20, 22 of the dielectric layer 18 have the thickness T1. The sections of the semiconductor layer 12 adjoining, and beneath, the overlying sections 26, 28 of the dielectric layer 24 have the thickness T2, which is less than the thickness T1.

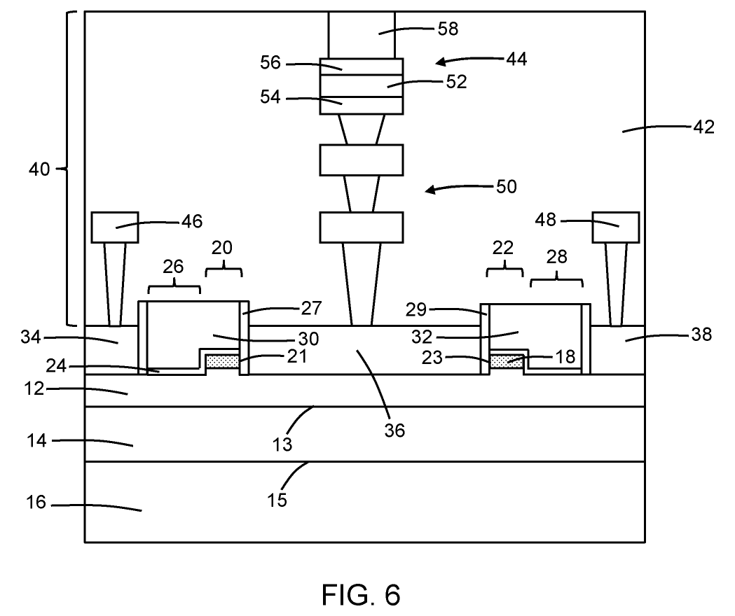

With reference to FIG. 6 in which like reference numerals refer to like features in FIG. 5 and at a subsequent fabrication stage, spacers 27 may be formed on the sidewalls of the gate electrode 30, including the sidewall 31 of the gate electrode 30 that is aligned with the side edge 21 of the section 20 of the dielectric layer 18. The spacer 27 adjacent to the side edge 21 extends fully past the section 20 of the dielectric layer 18 to the recessed top surface of the semiconductor layer 12. Spacers 29 may be formed on the sidewalls of the gate electrode 32, including the sidewall 33 of the gate electrode 32 that is aligned with the side edge 23 of the section 22 of the dielectric layer 18. The spacer 29 adjacent to the side edge 23 extends fully past the section 22 of the dielectric layer 18 to the recessed top surface of the semiconductor layer 12. The spacers 27, 29 may be comprised of one or more dielectric materials, such as silicon dioxide and silicon nitride, that are electrically insulating.

Source/drain regions 34, 36, 38 may be formed adjacent to the gate electrodes 30, 32 with the spacers 27, 29 providing electrical isolation. As used herein, the term “source/drain region” means a region of semiconductor material that can function as either a source or a drain of a field-effect transistor. The thick portion of the multiple-thickness gate dielectric layer beneath the gate electrode 30 is positioned adjacent to the source/drain region 36, and the thin portion of the multiple-thickness gate dielectric layer beneath the gate electrode 30 is positioned between the thick portion and the source/drain region 34. The thick portion of the multiple-thickness gate dielectric layer beneath the gate electrode 32 is positioned adjacent to the source/drain region 36, and the thin portion of the multiple-thickness gate dielectric layer beneath the gate electrode 32 is positioned between the thick portion and the source/drain region 38.

The gate electrode 30 and the multiple-thickness gate dielectric layer beneath the gate electrode 30 are laterally positioned between the source/drain region 34 and the source/drain region 36. The gate electrode 32 and the multiple-thickness gate dielectric layer beneath the gate electrode 32 are laterally positioned between the source/drain region 36 and the source/drain region 38. The gate electrodes 30, 32 and the respective multiple-thickness gate dielectric layers are laterally positioned between the source/drain region 34 and the source/drain region 38.

The source/drain regions 34, 36, 38 may include raised layers of a semiconductor material that are formed on the semiconductor layer 12. In an embodiment, the raised layers of the source/drain regions 34, 36, 38 may be formed by an epitaxial growth process and a dopant may be introduced during epitaxial growth. The source/drain regions 34, 36, 38 may further include doped portions that form inside the semiconductor layer 12 due to dopant diffusion from the raised layers during epitaxial growth. In an embodiment, the epitaxial growth of the raised layers of the source/drain regions 34, 36, 38 may be self-aligned by the gate electrodes 30, 32 and spacers 27, 29.

An interconnect structure 40 may be formed by middle-of-line processing and back-end-of-line processing. The interconnect structure 40 may include dielectric layers 42 belonging to multiple metallization levels that are arranged in a layer stack and a resistive memory element 44 that is formed in one or more of the dielectric layers 42. The dielectric layers 42 of the interconnect structure 40 may be comprised of dielectric materials, such as silicon dioxide, silicon nitride, tetraethylorthosilicate silicon dioxide, and/or fluorinated-tetraethylorthosilicate silicon dioxide, and metal features, such as wires and vias comprised of copper and aluminum, of the interconnect structure 40 may be disposed within the dielectric layers 42. In particular, a wire 46 may be coupled by contacts with the source/drain region 34, a wire 48 may be coupled by contacts with the source/drain region 38, and an interconnect 50 may be formed that includes metal features in multiple metallization levels of the interconnect structure 40.

The resistive memory element 44 includes a switching layer 52 that is positioned in a layer stack between a bottom electrode 54 and a top electrode 56. The bottom electrode 54 of the resistive memory element 44 is coupled by the interconnect 50 to the source/drain region 36, and the top electrode 56 of the resistive memory element 44 is coupled to a wire 58. The switching layer 52 may be comprised of a metal oxide, such as hafnium oxide, and the bottom electrode 54 and the top electrode 56 may be comprised of a metal, such as tantalum nitride.

The resistive memory element 44 can be programmed by changing the resistance across the switching layer 52 to provide different content-storage conditions, namely a high-resistance state and a low-resistance state, representing the stored bits of data. The switching layer 52 can be modified by applying a programming voltage across the bottom electrode 54 and top electrode 56 during a forming process that is sufficient to create one or more conductive filaments bridging across the thickness of the switching layer 52, which sets the low-resistance state. The conductive filaments can be destroyed, also by the application of a programming voltage across the bottom electrode 54 and top electrode 56, to reset the resistive memory element 44 to the high-resistance state. The content-storage condition of the resistive memory element 44 can be read by measuring a voltage drop across the resistive memory element 44.

The resistive memory element 44 may be deployed in an array of substantially-identical resistive memory elements of a resistive random-access memory device. The gate electrodes 30, 32 may represent gate fingers of an access transistor that are coupled to a word line in the interconnect structure 40. The wires 46, 48 may represent source lines of the resistive random-access memory device that are respectively coupled to the source/drain region 34 of the access transistor and the source/drain region 38 of the access transistor. The wire 58 may represent a bit line of the resistive random-access memory device that is coupled to the top electrode 56 of the resistive memory element 44. The source/drain region 34 of the access transistor is coupled by the interconnect 50 to the bottom electrode 54 of the resistive memory element 44.

The resistive memory element 44 and the access transistor including the gate electrodes 30, 32 may be considered to constitute a bitcell of the resistive random-access memory device. The thick portion of the multiple-thickness gate dielectric layer beneath the gate electrode 30 of the access transistor includes the section 20 of the dielectric layer 18 and is positioned adjacent to the source/drain region 36. The thick portion of the multiple-thickness gate dielectric layer beneath the gate electrode 32 of the access transistor includes the section 22 of the dielectric layer 18 and is also positioned adjacent to the source/drain region 36. The resistive memory element 44, which is coupled to the source/drain region 36, may be biased with a programming voltage for a short duration during a forming step associated with the resistive memory element 44 that forms conducting paths in the switching layer 52 and switches the resistive memory element 44 into a low-resistance state. The source/drain region 36 of the access transistor is protected by the resistive memory element 44 itself during forming. The thick portions of the multiple-thickness gate dielectric layer beneath the gate electrodes 30, 32 shield the access transistor from the programming voltage when other resistive memory elements in the array are being formed, which may improve the drain-source breakdown voltage and the breakdown voltage of the gate dielectric layer.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “directly contacting” another feature if intervening features are absent. A feature may be “indirectly on” or in “indirect contact” with another feature if at least one intervening feature is present. Different features may “overlap” if a feature extends over, and covers a part of, another feature. A feature may “overlie” another feature if a feature is positioned “over” another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor layer;
an access transistor including a first source/drain region, a second source/drain region, a first gate dielectric layer on the semiconductor layer, and a first gate electrode overlapped with the first gate dielectric layer, the first gate dielectric layer having a first portion with a first thickness adjacent to the first source/drain region and a second portion with a second thickness adjacent to the second source/drain region, and the first thickness greater than the second thickness; and
a resistive memory element coupled to the first source/drain region of the access transistor.

2. The structure of claim 1 wherein the first gate electrode and the first gate dielectric layer are laterally between the first source/drain region and the second source/drain region.

3. The structure of claim 1 wherein the first source/drain region is a drain of the access transistor, and the second source/drain region is a source of the access transistor.

4. The structure of claim 1 further comprising:
a dielectric layer having a first interface with the semiconductor layer,
wherein the semiconductor layer includes a first section with a first thickness relative to the first interface and a second section with a second thickness relative to the first interface, the first thickness is greater than the second thickness, and the first section of the semiconductor layer adjoins the first portion of the first gate dielectric layer.

5. The structure of claim 4 further comprising:
a semiconductor substrate having a second interface with the dielectric layer.

6. The structure of claim 4 wherein the first thickness and the second thickness are in a range of about 4 nanometers to about 20 nanometers.

7. The structure of claim 1 wherein the resistive memory element includes a first electrode, a second electrode, and a switching layer between the first electrode and the second electrode.

8. The structure of claim 7 further comprising:
an interconnect structure including an interconnection and a bit line,
wherein the first electrode of the resistive memory element is coupled by the interconnection to the first source/drain region, and the second electrode of the resistive memory element is coupled to the bit line.

9. The structure of claim 1 wherein the first portion of the first gate dielectric layer has a first width, and the second portion of the first gate dielectric layer has a second width that is greater than the first width.

10. The structure of claim 1 wherein the first gate electrode fully overlaps with the first gate dielectric layer.

11. The structure of claim 1 wherein the access transistor includes a second gate dielectric layer on the semiconductor layer, a third source/drain region, and a second gate electrode overlapped with the second gate dielectric layer, the second gate dielectric layer having a first portion with a third thickness adjacent to the first source/drain region and a second portion with a fourth thickness to the third source/drain region, and the third thickness is greater than the fourth thickness.

12. The structure of claim 11 wherein the first source/drain region is laterally positioned between the first portion of the first gate dielectric layer and the first portion of the second gate dielectric layer.

13. The structure of claim 11 wherein the third thickness is equal to the first thickness.

14. The structure of claim 13 wherein the fourth thickness is equal to the second thickness.

15. The structure of claim 11 wherein the first source/drain region is a drain of the access transistor, and the second source/drain region and the third source/drain region are sources of the access transistor.

16. The structure of claim 1 wherein the first portion of the first gate dielectric layer includes a first dielectric layer and a second dielectric layer that overlaps with the first dielectric layer.

17. The structure of claim 16 wherein the first dielectric layer and the second dielectric layer comprise a dielectric material.

18. The structure of claim 17 wherein the dielectric material is silicon dioxide.

19. The structure of claim 1 further comprising:
an interconnect structure including an interconnection,
wherein the resistive memory element includes an electrode coupled by the interconnection to the first source/drain region.

20. A method comprising:
forming an access transistor including a first source/drain region, a second source/drain region, a gate dielectric layer on a semiconductor layer, and a gate electrode overlapped with the gate dielectric layer, wherein the gate dielectric layer has a first portion with a first thickness adjacent to the first source/drain region and a second portion with a second thickness adjacent to the second source/drain region, and the first thickness is greater than the second thickness; and
forming a resistive memory element coupled to the first source/drain region of the access transistor.
